(19) United States
(12) Patent Application Publication
(10) Pub. No.: US 2026/0189190 A1
(43) Pub. Date: Jul. 2, 2026

(54) POWER AMPLIFIER CIRCUITS WITH DUAL-POLARITY

(71) Applicant: Telefonaktiebolaget LM Ericsson (publ), Stockholm (SE)

(72) Inventors: Christian ELGAARD, Lund (SE); Henrik SJÖLAND, Lund (SE)

(21) Appl. No.: 19/130,231

(22) PCT Filed: Nov. 17, 2022
(86) PCT No.: PCT/EP2022/082207

§ 371 Date: May 15, 2025

(51) Int. Cl. H03F 1/02; H03F 3/24

(52) U.S. Cl. CPC H03F 1/0233; H03F 3/245; H03F 2200/105; H03F 2200/36; H03F 2200/451

(57) ABSTRACT

A power amplifier circuit is provided. The power amplifier circuit has a first transistor arrangement, a first inductor, a second inductor and a third inductor coupled to a load. A first terminal of the first transistor arrangement is coupled to an input signal, a second terminal of the first transistor arrangement is coupled to a first supply voltage via the first inductor, a third terminal of the first transistor arrangement is coupled to a second supply voltage via the second inductor. The first and second inductors are coupled to the third inductor such that voltages over the first and second inductors are transformed to the load. The first transistor arrangement operates in a switching mode such that an output signal voltage with either a negative or positive amplitude proportional to the difference between the first and second supply voltages is provided to the load.

### TECHNICAL FIELD

Embodiments herein relate to power amplifier circuits. In particular, they relate to power amplifier circuits with dual polarity, as well as cartesian transmitters, polar transmitters and wireless communication devices comprising the power amplifier circuits.

### BACKGROUND

A wireless communication device or equipment usually comprises an antenna, a transceiver comprising transmitter and receiver, and a baseband processing unit. The transmitter typically up-converts baseband signals to Radio Frequency (RF) signals for transmission, and the receiver down-converts received RF signals to baseband signals for further processing in the baseband processing unit.

Power efficiency in transmitters is very important for power consumption in both wired and wireless communication devices and systems. High efficiency is difficult to obtain when the trend is towards higher data-rates which drives the wireless communication systems to use higher operating frequencies, higher channel bandwidths and higher order modulations that require the wireless communication systems to have both less distortion and higher peak to average power ratios. New solutions that can help obtain high efficiency in present and future wireless communication system, such as the 5^{th} and 6^{th} generation (5G/6G) wireless communication systems, are therefore highly desired.

Transmitters employ power amplifiers (PA) to increase RF signal power before transmission. A PA is expected to amplify input signals linearly and generate output signals with larger power but with identical characteristics to the input signals. A power back-off level in a PA is a power level below a saturation point at which the PA will continue to operate in the linear region even if there is a slight increase in the input power level. It is preferrable that a PA operates close to the saturation point as that is where efficiency is maximum. The amount by which the input or output power level is lowered relative to the maximum or peak output power level is called power back-off. Key to obtaining high efficiency in a transmitter for such a system with high order modulation is to provide high efficiency not only at peak output power, but also in power back-off levels. The reason is that the transmitter will spend a large part of the time in power back-off conditions, and more seldomly near the peak output power. One key technique is to modulate the supply voltage of the power amplifier according to the required output amplitude, so that the supply voltage is not higher than needed for the power amplifier to linearly amplify the signal, so called envelope tracking. Even higher efficiency can be obtained by operating the power amplifier in deep compression, in so called switched mode, and let the amplitude of the output signal be controlled by the supply voltage rather than by the input signal amplitude. The input signal can then be made constant envelope, containing just phase information. The amplitude and phase are thus used to represent the signal, rather than In-phase (I) and Quadrature-phase (Q) signal components, so a cartesian to polar coordinate transformation must be performed. This polar architecture is known as envelope elimination and restoration (EER). For signal modulations with a trajectory passing close to the origin of the constellation diagram, the polar signals have rapid transitions, resulting in wide bandwidth signals that are very difficult to process correctly. There are thus different polar architectures used, ranging from the pure polar EER, to the more cartesian-like envelope tracking, with different bandwidth-efficiency trade-offs.

There are also techniques for reducing the bandwidth expansion in polar transmitters, by avoiding the signal trajectory getting too close to the origin, by introducing deliberate errors, so called hole-punching. A recent idea is to instead go directly through the origin, by having an amplifier capable of using an amplitude signal with both polarities, in which case no abrupt transitions would be needed in amplitude and phase at a direct passage of the origin, see Jonas Lindstrand, “Integrated Transmitters for Cellular User Equipment—Wideband CMOS Power Amplifiers and Antenna Impedance Tuners”, PhD thesis, Lund University, 2019. However, more development in how to design such an amplifier is needed.

A technique to generate amplitude modulated signals from power amplifiers operating at constant amplitude is outphasing, where two or more power amplifiers generate signals that are out of phase with each other to generate low output signals when combined, or in phase with each other to generate large output signals when combined. Outphasing is a technique of improving efficiency at high peak to average power ratio (PAPR) values of transmitted signals. By modulating the phase difference between the two or more amplifier branches the output signal amplitude after the combiner can be controlled, and the phase modulation is then imposed as a common phase modulation to all amplifier branches. This is thus a polar architecture, with additional non-linear mapping between signal amplitude and phase difference, and hence it suffers from bandwidth expansion.

The ability for the signal trajectory to pass directly through origin without any abrupt phase transition with a two-branch outphasing amplifier was identified in patent U.S. Pat. No. 6,311,046. By then having one such amplifier for the I signal and one for the Q signal, a cartesian transmitter architecture based on outphasing can be created. No abrupt phase transitions are then needed, and the bandwidth expansion will be limited, as long as sufficient margin is left from the peak power of the transmitter, as the amplitude to phase difference becomes very non-linear at the extreme ends, i.e. the peak power. The amplifiers should have low output impedance, like class-D amplifiers, and a combiner is needed at the output to add the outputs of the I and Q amplifiers.

While the two-branch outphasing amplifier has the capability to allow the signal trajectory to pass through the origin without any abrupt signal transitions, it has some other shortcomings. The problems arise from the two branches operating at full output voltage amplitude also when only a small or zero output signal is needed. The switching losses of the amplifiers will thus be as large at low output amplitude as at large output amplitude, which is bad for back-off efficiency. Another issue is that the large signals present from the amplifiers will make the signal quality at low output amplitudes sensitive to the accuracy of the combiner. For instance, even a small imbalance in the I signal, the combiner will create a significant Q signal, and vice versa. Another concern is that the load impedance will have a large reactive part, especially at lower output amplitudes, the corresponding load current degrading back-off efficiency. It is also difficult to obtain the full output power of the I or Q amplifier, as the phase difference characteristic is heavily non-linear close to peak power.

### SUMMARY

Therefore, it is an object of embodiments herein to provide a power amplifier circuit with improved performance on efficiency, bandwidth and frequency.

According to one aspect of embodiments herein, the object is achieved by a power amplifier for amplifying an input signal and providing an output signal to a load. The power amplifier circuit comprises a first transistor arrangement comprising a first terminal, a second terminal and a third terminal. The power amplifier circuit further comprises a first inductor, a second inductor and a third inductor coupled to the load. The first terminal of the first transistor arrangement is coupled to the input signal, the second terminal of the first transistor arrangement is coupled to a first supply voltage via the first inductor, the third terminal of the first transistor arrangement is coupled to a second supply voltage via the second inductor. The first and second inductors are coupled to the third inductor such that voltages over the first and second inductors are transformed to the load and added constructively at the load. The first and second supply voltages are modulated individually between a first voltage level and a second voltage level. The second voltage level is higher than the first voltage level. The first transistor arrangement is operating in a switching mode such that an output signal voltage with either a negative or positive amplitude proportional to the difference between the first and second supply voltages is created and provided to the load.

According to some embodiments herein, the first transistor arrangement may comprise a metal-oxide-semiconductor (MOS) field-effect transistor, or a plurality of MOS transistors connected in parallel, or two anti-parallel MOS transistors.

According to some embodiments herein, the first and second supply voltages Vdd1, Vdd2 may be controlled linearly as a function of a target amplitude of the output signal voltage Vout, i.e. Vout=Vdd1−Vdd2. When the first supply voltage is at the first voltage level, e.g. zero or at a minimum value, and the second supply voltage is at the second voltage level, e.g. a maximum value, the output signal voltage is at the maximum value with negative amplitude. When the first supply voltage is at the second voltage level, e.g. the maximum value and the second supply voltage is at the minimum value, e.g. zero, the output signal voltage is at the maximum value with positive amplitude. When the first and second supply voltages are both halfway between the first and the second voltage levels, e.g. between zero and the maximum value, the output signal voltage is at the minimum value or zero.

In other words, embodiments herein provide a power amplifier circuit with dual polarity by using the property of MOS transistors that drain and source terminals are interchangeable depending on their voltage levels. The power amplifier circuit according to embodiments herein has a symmetric structure which is capable of providing an output signal Vout with both polarities. That is Vout =Vdd1−Vdd2, which may be either positive or negative, resulting in opposite phases of the output signal, represented as the output signal with either a positive or negative amplitude According to embodiments herein, the drain and source terminals of the MOS transistor comprised in the power amplifier circuit are connected to individual voltage supplies through respective inductors. The input signal is connected to the gate and has a rather large voltage amplitude without modulation to drive the MOS transistor in switching mode. The amplitude modulation is imposed on the two supply voltages. The first and second supply voltages are modulated individually between the first voltage level and the second voltage level. The ranges of the first and second voltage levels may be located at any level with respect to the signal ground, including both positive and negative voltages depending on the desired output signal amplitude. The first voltage level may be, e.g. a minimum value or 0, the second voltage level may be, e.g. a maximum value. When both supply voltages are equal, the output signal voltage is at the minimum value or zero, and when the first supply voltage is at the maximum value and the second supply voltage is at zero, the output signal voltage is positive with the maximum amplitude. When the first supply voltage is at zero and the second supply voltage is at the maximum value, the output signal voltage is negative with the maximum value.

The inductors between the supplies and the drain and source terminals of the MOS transistor are coupled to the output by one or more inductors in series with the load so that their voltages are added up. An output signal voltage with an amplitude proportional to the difference between the two supply voltages will then be created and provided to the load. Modulating the two supply voltages individually and linearly between the first and second voltage levels, e.g. between zero and the maximum value, voltage differences of both polarities can be created.

Some advantages of the power amplifier circuit according to embodiments herein are but not limited to:
The supply voltages may be controlled linearly as a function of the target output signal amplitude, so bandwidth expansion is reduced, and the supply modulator bandwidth requirements are also minimized.
High power back-off efficiency due to minimized reactive load current and zero supply voltage difference at zero output signal amplitude.
Suitable for high frequency, mm-wave, applications since the parasitic capacitances of the drain and source terminals of the transistor in the power amplifier circuit may be used to resonate with the corresponding inductor at a desired frequency.
Automatic healing of electromigration damage of metals in inductors and transistors as the direct current (DC) current will flow in opposite directions for positive and negative output signal amplitudes.
May be used for polar or cartesian transmitters.
When used in a cartesian transmitter, an efficient transmitter without troublesome time alignment is provided. That is no time alignment between amplitude and phase is needed as it is needed in a polar transmitter since supply modulation controls amplitude of both I and Q signals, which also controls the phase of the output signal.
When used in a polar transmitter, an efficient transmitter with less bandwidth expansion issues than a conventional polar transmitter is provided.

Therefore, embodiments herein provide a power amplifier circuit with improved performance on efficiency, bandwidth and frequency.

### BRIEF DESCRIPTION OF THE DRAWINGS

Examples of embodiments herein are described in more detail with reference to attached drawings in which:

FIG. 1 is a schematic view of one example of a power amplifier circuit according to embodiments herein;

FIG. 2 is a schematic view of another example of a power amplifier circuit according embodiments herein;

FIG. 3 is a schematic view of another example of a power amplifier circuit according to embodiments herein;

FIG. 4 is a schematic view of a cartesian transmitter according to embodiments herein;

FIG. 5 is a schematic view of a polar transmitter according to embodiments herein;

FIG. 6 is a plot showing simulation results of the power amplifier circuit according to embodiments herein;

FIG. 7 is a plot showing simulation results of the power amplifier circuit according to embodiments herein;

FIG. 8 is a plot showing simulation results on power added efficiency of the power amplifier circuit according to embodiments herein;

FIG. 9 is a plot showing time domain simulation results of the power amplifier circuit according to embodiments herein; and

FIG. 10 is a block diagram illustrating a wireless communication device in which a power amplifier circuit according to embodiments herein may be implemented.

### DETAILED DESCRIPTION

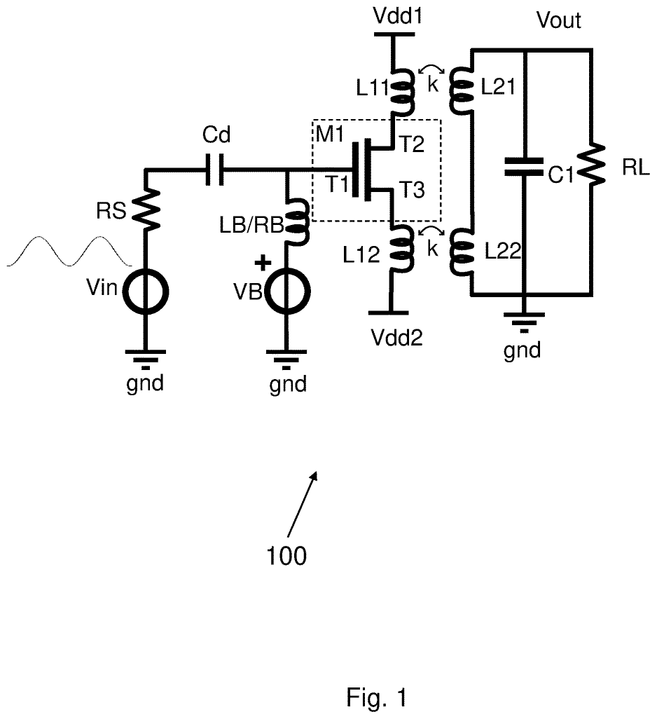

FIG. 1 shows a schematic view of a power amplifier circuit 100 for amplifying an input signal Vin and providing an output signal Vout to a load RL. The power amplifier circuit 100 comprises a first transistor arrangement M1 comprising a first terminal T1, a second terminal T2 and a third terminal T3. The power amplifier circuit 100 further comprises a first inductor L11 and a second inductor L12 and a third inductor L21, L22 coupled to the load RL. The first terminal T1 of the first transistor arrangement M1 is coupled to the input signal Vin, the second terminal T2 of the first transistor arrangement M1 is coupled to a first supply voltage Vdd1 via the first inductor L11, the third terminal T3 of the first transistor arrangement M1 is coupled to a second supply voltage Vdd2 via the second inductor L12.

According to some embodiments herein, as shown in FIG. 1, the third inductor may be a single inductor or comprise two inductors L21, L22 connected in series with each other and with the load RL, and the first and second inductors L11, L12 are coupled to the two inductors L21, L22 respectively. k is coupling coefficient between the first/second inductor L11/L12 and the third inductor L21, L22.

According to some embodiments herein, the third inductor, i.e. the two inductors L21, L22 may form a differential inductor connected in series to the load RL, and the first and second inductors L11, L12 are coupled to the differential inductor.

The first and second inductors L11, L12 are coupled to the third inductor L21, L22 such that voltages over the first and second inductors L11, L12 are transformed to the load RL and added constructively at the load RL.

The first and second supply voltages Vdd1, Vdd2 are modulated individually between a first voltage level and a second voltage level. The second voltage level is higher than the first voltage level. The first transistor arrangement M1 is operating in a switching mode such that an output signal voltage Vout with either a negative or positive amplitude proportional to the difference between the first and second supply voltages, i.e. Vout=Vdd1−Vdd2, is created and provided to the load RL.

VB is a bias voltage source and coupled to the first terminal T1 via a bias inductor LB or resistor RB, RS is the source impedance or resistance of the input signal Vin, and Cd is an AC-coupling capacitor preventing unnecessary DC current flow between the voltage sources VB and Vin.

As shown in FIG. 1, the first transistor arrangement M1 comprises a metal-oxide-semiconductor (MOS) field-effect transistor. The first terminal T1 is a gate terminal of the MOS transistor, the second terminal T2 is a drain or source terminal of the MOS transistor, and the third terminal T3 is a source or drain terminal of the MOS transistor.

The MOS transistor M1 will operate as a switch, connecting its two supply voltages Vdd1, Vdd2 together when closing, making the output signal amplitude Vout equal to the supply voltage difference. The direction of the current flow through the MOS transistor M1 will depend on which supply voltage is larger.

The first and second supply voltages Vdd1, Vdd2 may be controlled linearly as a function of a target amplitude of the output signal voltage Vout. For examples, when the first supply voltage Vdd1 is at the first voltage level, e.g. 0 or a minimum value Vmin, and the second supply voltage Vdd2 is at the second voltage level, e.g. a maximum value Vmax, the output signal voltage Vout is negative with the maximum value, i.e. −Vmax, when the first supply voltage Vdd1 is at the maximum Vmax and the second supply voltage Vdd2 is zero, the output signal voltage Vout is positive with the maximum value, i.e. +Vmax, and when the first and second supply voltages Vdd1, Vdd2 are both halfway between the first and second voltage levels, e.g. zero and the maximum value, the output signal voltage Vout is zero or at the minimum value Vmin. The ranges of the first and second voltage levels may be located at any level with respect to the signal ground, including both positive and negative voltages depending on the desired output signal amplitude.

Different control equations may be created for the two supply voltages, mapping the target output signal amplitude to the supply voltages, all providing the same voltage difference but with different amount of average voltage, i.e. common mode voltage. In this case a linear characteristic, similar to that of the currents in a push-pull class A amplifier, is preferred for the two supply voltages versus output signal amplitude, to minimize bandwidth expansion due to non-linearities, that would otherwise require faster supply modulators.

The inductors between the supplies and the drain and source terminals of the MOS transistor are coupled to one or more inductors in series with the load so that their voltages are added up at the output. An output signal voltage with an amplitude proportional to the difference between the two supply voltages will then be created and provided to the load. Modulating the two supply voltages individually between the first and second voltage levels, e.g. between zero and the maximum value, voltage differences of both polarities can be created.

In case the MOS transistor M1 has non-symmetric drain and source regions due to drain engineering, the MOS transistor may be split into two anti-parallel devices to obtain better circuit symmetry.

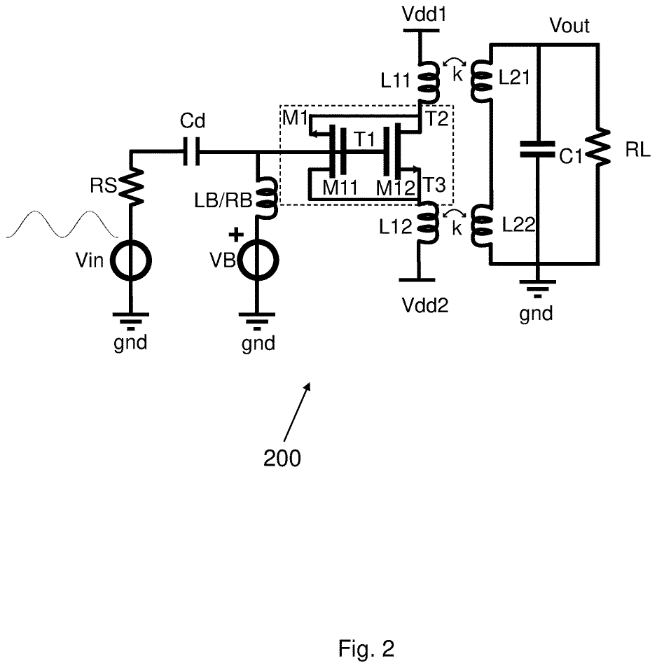

FIG. 2 shows a schematic view of a power amplifier circuit 200, where the first transistor arrangement M1 comprises a first MOS transistor M11 and a second MOS transistor M12. The gates of the first and second MOS transistors M11, M12 are connected together to form the first terminal T1 of the first transistor arrangement M1, the drain of the first MOS transistor M11 and the source of the second MOS transistor M12 are connected together to form the second terminal T2 of the first transistor arrangement M1, and the source of the first MOS transistor M11 and the drain of the second MOS transistor M12 are connected together to form the third terminal T3 of the first transistor arrangement M1.

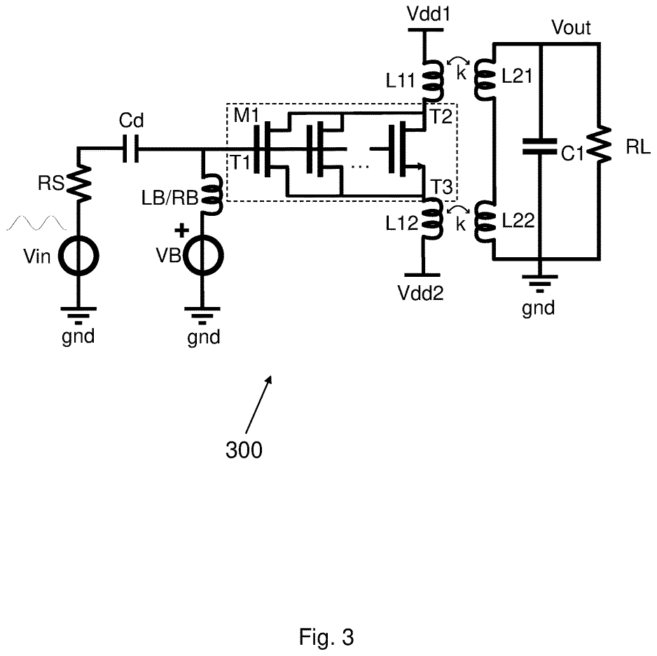

According to some embodiments herein, the first transistor arrangement M1 may also comprise a plurality of MOS transistors connected in parallel, as shown in FIG. 3, where the gates of the plurality of MOS transistors are connected together to form the first terminal T1 of the first transistor arrangement M1, the drains of the plurality of MOS transistors are connected together to form the second terminal T2 of the first transistor arrangement M1, and the sources of the plurality of MOS transistors are connected together to form the third terminal T3 of the first transistor arrangement M1.

The MOS transistor in the power amplifier circuit 100, 200, 300 operates as a switch, connecting its two supply voltages together when closing, making the output signal amplitude equal to the difference of the two supply voltages. The direction of the current flow through the MOS transistor will depend on which supply voltage is larger. The current flowing out from one voltage supply will flow into the other voltage supply and charge it, and the two voltage supplies will take turns charging each other in this way. This results in an automatic healing of electromigration damage of metals in inductors and transistors as the direct current (DC) current will flow in opposite directions for positive and negative output signal amplitudes. Moreover, the common-mode voltage can have larger amplitude which will not cause additional power losses, and the common mode voltage can be chosen freely, so the output signal amplitude to supply voltage characteristics can be linear to minimize the bandwidth expansion. If the common-mode voltage may instead have to be reduced, that may be achieved by a non-linear characteristic of the output signal amplitude to supply voltage, which will result in bandwidth expansion that will require faster supply modulators.

The power amplifier circuit 100, 200, 300 operates as a switched mode amplifier with supply modulation, so high efficiency can be obtained at both peak power and in power back-off conditions. The power amplifier circuit 100, 200, 300 has linearly modulated supply voltages and dual polarity output signal amplitude which allows the signal trajectory to pass directly through the origin of the constellation plane with purely linear signal behaviour. The power amplifier circuit 100, 200, 300 with dual polarity can thus be used in a polar transmitter where the trajectory is able to pass directly through the origin, which provides degrees of freedom that can be used for bandwidth reduction, or in a cartesian transmitter with two power amplifier circuits, one for the In-phase (I) signal and one for the Quadrature-phase (Q) signal, and with a combiner for combining the I and Q signals at the output of the transmitter.

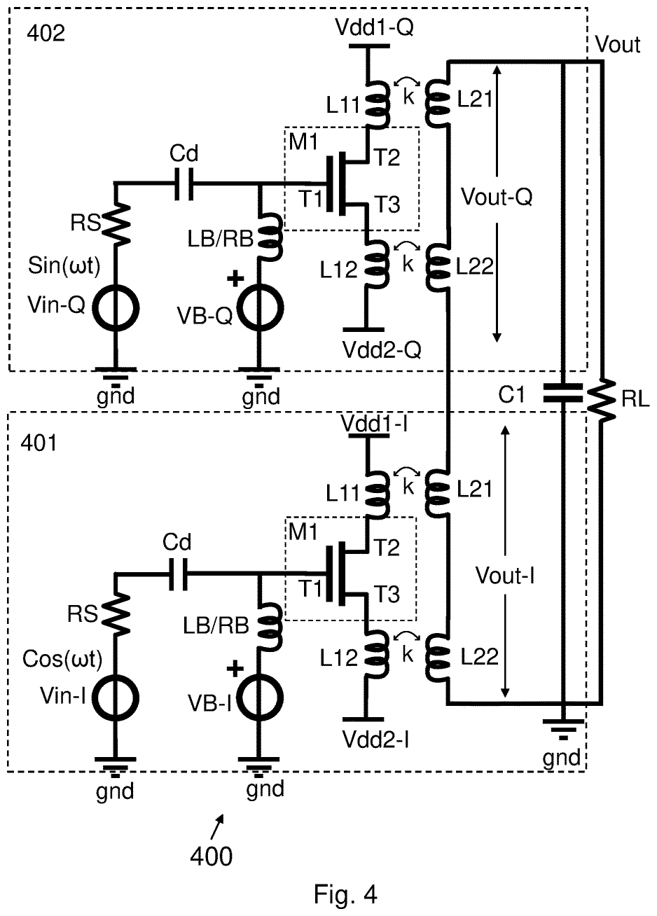

Therefore, the power amplifier circuits 100, 200, 300 may be used to implement a cartesian transmitter. FIG. 4 shows a cartesian transmitter 400 comprising two power amplifier circuits 401, 402 according to embodiments herein. The first power amplifier circuit 401 is for amplifying an I input signal Vin-I and outputting an I signal Vout-I. The second power amplifier circuit 402 is for amplifying a Q input signal Vin-Q and outputting a Q signal Vout-Q. The third inductors L21, L22 of the two power amplifier circuits 401, 402 are connected in series with each other and with the load RL such that the I and Q output signals Vout-I, Vout-Q are combined to an output signal Vout and provided to the load RL. To simplify the drawing, the name annotations for the components in the I and Q power amplifier circuits 401, 402 are the same except for the voltage sources and output voltages for the I and Q power amplifier circuits 401, 402.

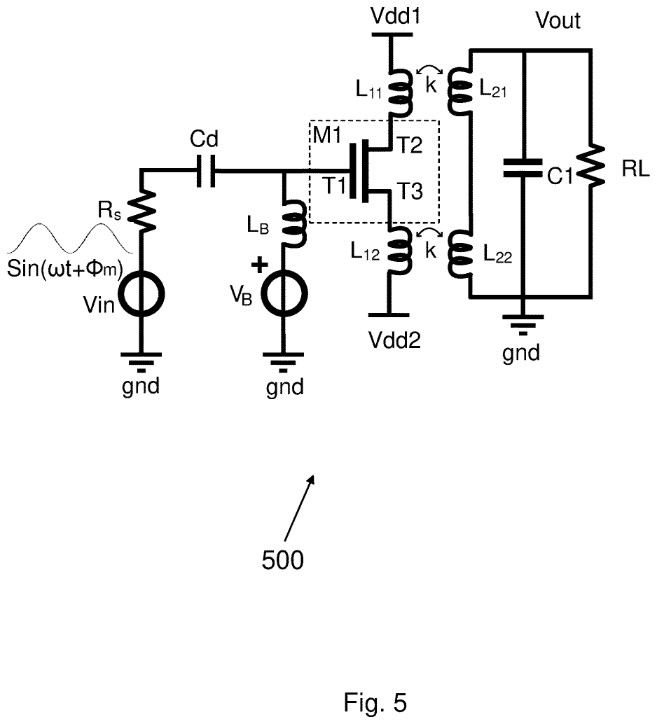

The power amplifier circuits 100, 200, 300 may also be used to implement a polar transmitter. FIG. 5 shows a polar transmitter 500 comprising one power amplifier circuit 100, 200, 300 according to embodiments herein. The input signal Vin to the gate of the transistor M1 is not a pure sinusoidal. Instead, it is a phase modulated constant amplitude signal sin(ωt+Φm). The amplitude modulation is added by modulating Vdd1 and Vdd2 similar to as described above.

The polar transmitter 500 has an advantage over a standard polar transmitter. It can do a 180-degree phase shift by crossing the origin in the IQ-constellation diagram without any abrupt signal transitions occurring inside the circuit. This helps to mitigate the well-known problem with bandwidth expansion when going from cartesian coordinates to polar coordinates.

To demonstrate the principle and performance of the power amplifier circuits 100, 200, 300, an example circuit is set up and simulated. The first transistor arrangement M1 in the example circuit comprises 8 NMOS transistors each having a size of 5 um in width and 20 nm in length. The input signal Vin is a constant amplitude signal with the amplitude of −3 dBm, the input signal frequency is 25 GHz, the source impedance RS is 50 ohm. The values of the other circuit elements are LB=1.44 nH, VB=0.5V, L11, L12, L21, L22=200 pH, k=−0.9, C1=0.2 pF, RL=50 ohm. The supply voltages Vdd1 and Vdd2 are modulated between 0V and 1V.

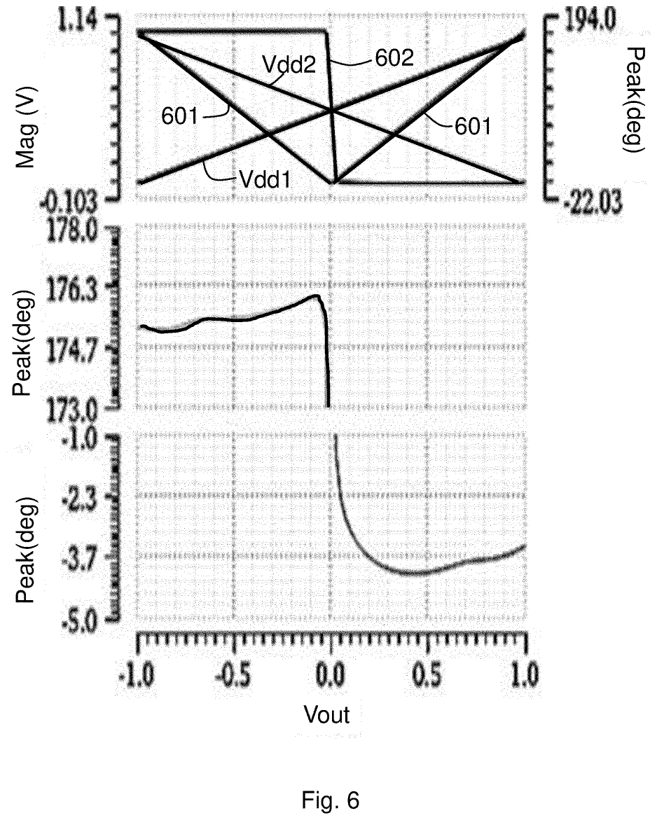

FIG. 6 shows simulation results where the first and second supply voltages Vdd1 and Vdd2 are swept versus the target output signal voltage amplitude Vout from a negative value of −1 to a positive value of +1 which are normalized values relative to the supply voltages. The upper plot is the supply voltages Vdd1, Vdd2 and the output signal magnitude indicated by 601, referring to the vertical axis to the left, and the output signal phase indicated by 602 referring to the vertical axis to the right. The middle plot is the phase for negative output signal, the lower plot is the phase for positive output signal.

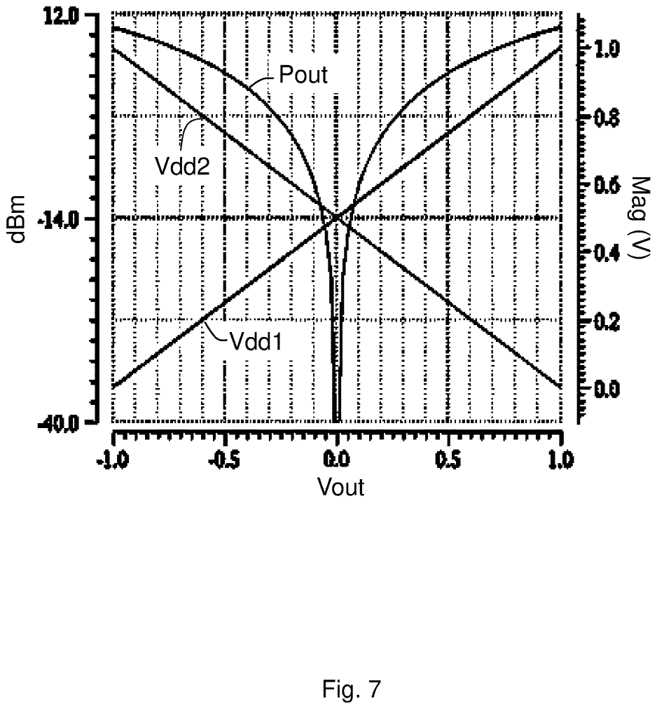

FIG. 7 shows output power Pout in dBm for positive and negative output signals, referring to the vertical axis to the left and the corresponding supply voltages Vdd1 and Vdd2, referring to the vertical axis to the right.

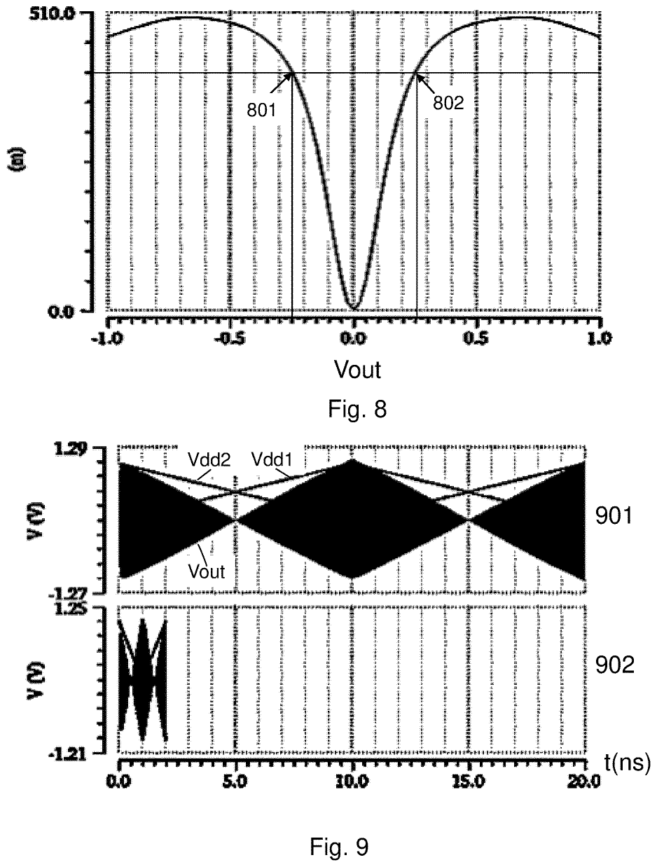

FIG. 8 shows the power added efficiency (PAE) which is close to 50% above ˜12 dB power back-off level, i.e. when the output signal amplitude is above 0.25 V and below −0.25V, indicated by arrows 801, 802.

FIG. 9 shows time domain simulation results. In plot 901, the two supply voltages Vdd1 and Vdd2 are modulated to produce a 10 ns voltage ramp from 0 V to 1 V and from 1 V to 0 V respectively, the output signal Vout with positive and negative values proportional to the difference between the two supply voltages is generated. In plot 802, similar simulation results are shown but the two supply voltages Vdd1 and Vdd2 are modulated to produce a voltage ramp with 1 ns, i.e. 10 times faster, to demonstrate that the power amplifier circuit 100, 200, 300 has the capability to support high bandwidth modulation.

From the results of the simulations, it can be seen that the power amplifier circuit 100, 200, 300 has good linearity and high back-off efficiency.

Those skilled in the art will understand that the power amplifier circuits 100, 200, 300, the Cartesian transmitter 400 and the Polar transmitter 500 according to embodiments herein may be implemented by any semiconductor technology, e.g. N-type Metal Oxide Semiconductor (NMOS), P-type Metal Oxide Semiconductor (PMOS), Complementary Metal Oxide Semiconductor (CMOS), Silicon on Insulator (SOI) CMOS, fin field-effect transistor (finFET), MOSFET or Micro-Electro-Mechanical Systems (MEMS) technology etc. The power amplifier circuit 100, 200, 300 and the Cartesian and Polar transmitters 400, 500 according to embodiments herein may be fully integrated on chip.

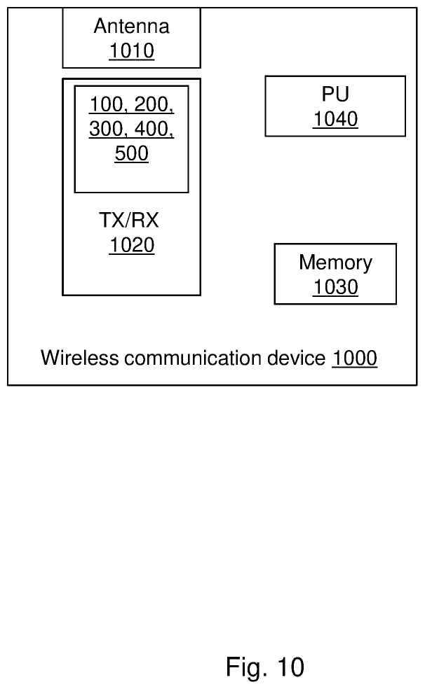

The power amplifier circuits 100, 200, 300 and the Cartesian and Polar transmitters 400, 500 according to embodiments herein may be employed in various integrated circuits, electronic circuits or devices, communication devices or apparatus. FIG. 10 shows a block diagram of a wireless communication device 1000 in which the power amplifier circuits 100, 200, 300 and the Cartesian and Polar transmitters 400, 500 according to embodiments herein may be implemented. The wireless communication device 1000 comprises an antenna 1010, a transceiver TX/RX 1020 which comprises the power amplifier circuit 100, 200, 300 and the Cartesian and Polar transmitters 400, 500 according to embodiments herein. The wireless communication device 1000 may comprise other units, where a memory 1030, and a processing unit PU 1040 are shown. The wireless communication device 1000 may be a user equipment or a mobile device for a cellular communication system. User equipment is a non-limiting term which means any terminal, wireless communication terminal, Machine Type Communication (MTC) device, Device to Device (D2D) terminal, or node e.g. smart phone, laptop, mobile phone, sensor, relay, mobile tablets or even a small base station communicating within a cell.

To summarize, embodiments herein provide a power amplifier circuit 100, 200, 300 with dual polarity by using the property of MOS transistors that drain and source terminals are interchangeable depending on their voltage levels. The power amplifier circuit 100, 200, 300 according to embodiments herein has a symmetric structure which is capable of providing an output signal Vout with both polarities, i.e. Vout=Vdd1−Vdd2 which may be either positive or negative, resulting in opposite phases of the output signal, represented as the output signal with positive and negative amplitude. According to embodiments herein, the drain and source terminals of the MOS transistor comprised in the power amplifier circuit are connected to individual voltage supplies through respective inductors. The input signal is connected to the gate and has a rather large voltage amplitude without modulation to drive the MOS transistor in switching mode. The amplitude modulation is imposed on the two supply voltages. The first and second supply voltages are modulated individually between the first voltage level and the second voltage level. The first voltage level may be, e.g. a minimum value or 0, the second voltage level may be, e.g. a maximum value, depending on the desired output signal amplitude. When both supply voltages are equal, the output signal voltage is at the minimum value or zero, and when the first supply voltage is at the maximum value and the second supply voltage is at zero, the output signal voltage is positive with the maximum value. When the first supply voltage is at zero and the second supply voltage is at the maximum value, the output signal voltage is negative with the maximum value.

The word “comprise” or “comprising”, when used herein, shall be interpreted as non-limiting, i.e. meaning “consist at least of”.

The embodiments herein are not limited to the above described preferred embodiments. Various alternatives, modifications and equivalents may be used. Therefore, the above embodiments should not be taken as limiting the scope of the invention, which is defined by the appended claims.

1. A power amplifier circuit for amplifying an input signal and providing an output signal to a load, the power amplifier circuit comprising:
a first transistor arrangement comprising a first terminal, a second terminal and a third terminal;
a first inductor;
a second inductor; and
a third inductor coupled to the load;
the first terminal of the first transistor arrangement is coupled to the input signal;
the second terminal of the first transistor arrangement is coupled to a first supply voltage via the first inductor;
the third terminal of the first transistor arrangement is coupled to a second supply voltage via the second inductor;
the first and second inductors are coupled to the third inductor such that voltages over the first and second inductors are transformed to the load and added constructively at the load;
the first and second supply voltages are modulated individually between a first voltage level and a second voltage level, the second voltage level being higher than the first voltage level; and
the first transistor arrangement is operating in a switching mode such that the output signal voltage with either a negative or positive amplitude proportional to the difference between the first and second supply voltages is created and provided to the load.

2. The power amplifier circuit according to claim 1, wherein the first transistor arrangement comprises a metal-oxide-semiconductor, MOS, field-effect transistor, and the first terminal is a gate terminal of the MOS transistor, the second terminal is a drain or source terminal of the MOS transistor, and the third terminal is a source or drain terminal of the MOS transistor.

3. The power amplifier circuit according to claim 1, wherein the first transistor arrangement comprises a first metal-oxide-semiconductor, MOS, transistor and a second MOS transistor wherein gates of the first and second MOS transistors are connected together to form the first terminal of the first transistor arrangement, a drain of the first MOS transistor and a source of the second MOS transistor are connected together to form the second terminal of the first transistor arrangement and a source of the first MOS transistor and a drain of the second MOS transistor are connected together to form the third terminal of the first transistor arrangement.

4. The power amplifier circuit according to claim 1, wherein the first transistor arrangement comprises a plurality of metal-oxide-semiconductor, MOS, field-effect transistors connected in parallel.

5. The power amplifier circuit according to claim 1, wherein the third inductor comprises two inductors connected in series with each other and with the load, and the first and second inductors are coupled to the two inductors respectively.

6. The power amplifier circuit according to claim 5, wherein the two inductors form a differential inductor.

7. The power amplifier circuit according to claim 1, wherein the third inductor comprises a single inductor.

8. The power amplifier circuit according to claim 1, wherein the first and second supply voltages are controlled linearly as a function of a target amplitude of the output signal voltage such that when the first supply voltage is at the first voltage level and the second supply voltage is at the second voltage level, the output signal voltage is negative with the maximum value, when the first supply voltage is at the second voltage level and the second supply voltage is at the first voltage level, the output signal voltage is positive with the maximum value, and when the first and second supply voltages are both halfway between the first and second voltage levels, the output signal voltage is at a minimum value or zero.

9. The power amplifier circuit according to claim 1, wherein the power amplifier circuit is fully integrated on chip.

10. A cartesian transmitter comprising a first power amplifier circuits for amplifying an In-phase input signal and providing an In-phase output signal and a second power amplifier circuit for amplifying a Quadrature-phase signal and providing a Quadrature-phase output signal, each of the first and second power amplifier circuits comprising:
a first transistor arrangement comprising a first terminal, a second terminal and a third terminal;
a first inductor;
a second inductor; and
a third inductor coupled to a load;
the first terminal of the first transistor arrangement is coupled to an input signal;
the second terminal of the first transistor arrangement is coupled to a first supply voltage via the first inductor;
the third terminal of the first transistor arrangement is coupled to a second supply voltage via the second inductor;
the first and second inductors are coupled to the third inductor such that voltages over the first and second inductors are transformed to the load and added constructively at the load;
the first and second supply voltages are modulated individually between a first voltage level and a second voltage level, the second voltage level being higher than the first voltage level;
the first transistor arrangement is operating in a switching mode such that an output signal voltage with either a negative or positive amplitude proportional to the difference between the first and second supply voltages is created and provided to the load;
the input signal for the first power amplifier circuit being the In-phase input signal;
the input signal for the second power amplifier circuit being the Quadrature-phase signal;
the output signal voltage of the for the first power amplifier circuit being circuit being a voltage of In-phase output signal; and
the output signal voltage of the for the first power amplifier circuit being circuit being a voltage of the Quadrature-phase output signal.

11. The cartesian transmitter according to claim 10, wherein the third inductors of the two power amplifier circuits are connected in series with each other and with the load such that the In-phase and Quadrature-phase output signals are combined at the load.

12. A polar transmitter comprising a power amplifier circuit for amplifying an input signal and providing an output signal to a load, the power amplifier circuit comprising:
a first transistor arrangement comprising a first terminal, a second terminal and a third terminal;
a first inductor;
a second inductor; and
a third inductor coupled to the load;
the first terminal of the first transistor arrangement is coupled to an input signal;
the second terminal of the first transistor arrangement is coupled to a first supply voltage via the first inductor;
the third terminal of the first transistor arrangement is coupled to a second supply voltage via the second inductor;
the first and second inductors are coupled to the third inductor such that voltages over the first and second inductors are transformed to the load and added constructively at the load;
the first and second supply voltages are modulated individually between a first voltage level and a second voltage level, the second voltage level being higher than the first voltage level; and
the first transistor arrangement is operating in a switching mode such that the output signal voltage with either a negative or positive amplitude proportional to the difference between the first and second supply voltages is created and provided to the load.

13. The power amplifier circuit according to claim 1, wherein the power amplifier circuit is comprised in a wireless communication device.

14. The power amplifier circuit according to claim 13, wherein the wireless communication device is a user equipment or a base station for a cellular communications system.

15. The power amplifier circuit according to claim 2, wherein the third inductor comprises two inductors connected in series with each other and with the load, and the first and second inductors are coupled to the two inductors respectively.

16. The power amplifier circuit according to claim 15, wherein the two inductors form a differential inductor.

17. The power amplifier circuit according to claim 3, wherein the third inductor comprises two inductors connected in series with each other and with the load, and the first and second inductors are coupled to the two inductors respectively.

18. The power amplifier circuit according to claim 17, wherein the two inductors form a differential inductor.

19. The power amplifier circuit according to claim 4, wherein the third inductor comprises two inductors connected in series with each other and with the load, and the first and second inductors are coupled to the two inductors respectively.

20. The power amplifier circuit according to claim 2, wherein the first and second supply voltages are controlled linearly as a function of a target amplitude of the output signal voltage such that when the first supply voltage is at the first voltage level and the second supply voltage is at the second voltage level, the output signal voltage is negative with the maximum value, when the first supply voltage is at the second voltage level and the second supply voltage is at the first voltage level, the output signal voltage is positive with the maximum value, and when the first and second supply voltages are both halfway between the first and second voltage levels, the output signal voltage is at a minimum value or zero.
